(19) United States
(12) Patent Application Publication
(10) Pub. No.: US 2024/0397696 A1
(43) Pub. Date: Nov. 28, 2024

(54) SEMICONDUCTOR STORAGE DEVICE

(71) Applicant: Socionext Inc., Kanagawa (JP)

(72) Inventor: Masanobu HIROSE, Yokohama-shi (JP)

(21) Appl. No.: 18/796,001

(22) Filed: Aug. 6, 2024

Related U.S. Application Data
(63) Continuation of application No. PCT/JP2023/004369, filed on Feb. 9, 2023.

(30) Foreign Application Priority Data
Feb. 17, 2022 (JP) 2022-022644

(51) Int. Cl. H10B 10/00

(52) U.S. Cl. CPC H10B 10/125

(57) ABSTRACT

A 1-port SRAM cell includes: a load transistor, a load transistor, a drive transistor, a drive transistor, an access transistor having nodes, one of which is connected to a buried interconnect and a line; and an access transistor having nodes, one of which is connected to a buried interconnect and a line. The buried interconnects are formed in the buried interconnect layer so as to extend in the Y-direction, and the lines are formed in the first line layer located above the buried interconnect layer so as to extend in the Y-direction.

### CROSS-REFERENCE TO RELATED APPLICATIONS

This is a continuation of International Patent Application No. PCT/JP2023/004369, filed on Feb. 9, 2023, which claims priority to Japanese Patent Application No. 2022-022644, filed on Feb. 17, 2022. The entire disclosures of these applications are incorporated by reference herein.

### BACKGROUND

The present disclosure relates to a semiconductor memory device, and particularly to a layout configuration of 1-port and 2-port SRAM (Static Random Access Memory) cells (hereinafter simply referred to as cells where appropriate).

An SRAM is widely used for semiconductor integrated circuits.

To achieve high integration of a semiconductor integrated circuit, use of not a line provided in a metal line layer formed above transistors as in a traditional way but a line provided in a buried interconnect (BI) layer has been provided.

R. Mathur et al, “Buried Bitline for sub-5 nm SRAM Design”, 2020 IEEE International Electron Devices Meeting (IEDM), December 2020, IEDM20-409-412 discloses a layout configuration of a 1-port SRAM cell in which a bit line pair is provided in a buried interconnect layer.

### SUMMARY

However, currently, lines used in the buried interconnect layer assumes metal material such as tungsten, which is higher in resistance than copper used in general in lines of a semiconductor integrated circuit. Accordingly, if a line in the buried interconnect layer is used as a bit line, the SRAM cells operate reading and writing at a lower speed, and the writing characteristics of the SRAM cell is deteriorated. Thus, an operational lower limit voltage increases. If the line width of the bit line in the buried interconnect layer is increased to improve the operational lower limit voltage of the SRAM cell, the area of the SRAM cell becomes larger. Even if the length of the bit line in the depth direction of the line is extended to reduce the resistance of the line, such a reduction is limited due to the manufacturing restriction. In addition, due to a larger parasitic capacitance, the operation speed decreases.

It is an object of the present disclosure to provide the layout configuration of the SRAM cell where the bit lines are provided in the buried interconnect layer so that the semiconductor memory device can operate at a high speed and its writing characteristic can be improved whereas the area of the semiconductor memory device is less increased.

A first aspect of the present disclosure is a semiconductor memory device including a 1-port SRAM cell, wherein the 1-port SRAM cell includes a first transistor having nodes, one of which is connected to a first power source that supplies a first voltage, and another one of which is connected to a first node, and having a gate connected to a second node, a second transistor having nodes, one of which is connected to the first power source, and another one of which is connected to the second node, and having a gate connected to the first node, a third transistor having nodes, one of which is connected to the first node, and another one of which is connected to a second power source that supplies a second voltage different from the first voltage, and having a gate connected to the second node, a fourth transistor having nodes, one of which is connected to the second node, another one of which is connected to the second power source, and having a gate connected to the first node, a fifth transistor having nodes, one of which is connected to a first bit line, another one of which is connected to the first node, and having a gate connected to a word line, and a sixth transistor having nodes, one of which is connected to a second bit line with which the first bit line constitute a complementary bit line pair, and another one of which is connected to the second node, and having a gate connected to the word line, the first bit line includes a first buried interconnect formed in a buried interconnect layer and extending in a first direction, and a first line formed in a first line layer located above the first to sixth transistors and extending in the first direction, the second bit line includes a second buried interconnect formed in the buried interconnect layer and extending in the first direction, and a second line formed in the first line layer and extending in the first direction.

According to the present disclosure, the first bit line includes a first buried interconnect formed in a buried interconnect layer, and a first line formed in the first line layer, and the second bit line includes a second buried interconnect formed in a buried interconnect layer, and a second line formed in the first line layer. That is, the first bit line and the second bit line are each formed in the buried interconnect layer and in the M1 line layer. Accordingly, the resistance values of the first and second bit lines can be reduced, and thus the semiconductor memory device can operate at a high speed and its writing characteristic can be improved. Further, the first and second bit lines are formed in each of the buried interconnect layer and the M1 line layer, and thus, the resistance values of the bit lines can be reduced whereas the area of the semiconductor memory device is less increased. Accordingly, the semiconductor memory device can operate at a high speed and its writing characteristic can be improved whereas the area of the semiconductor memory device is less increased.

A second aspect of the present disclosure is a semiconductor memory device including a 2-port SRAM cell, wherein the 2-port SRAM cell includes a first transistor having nodes, one of which is connected to a first power source that supplies a first voltage, and another one of which is connected to a first node, and having a gate connected to a second node, a second transistor having nodes, one of which is connected to the first power source, and another one of which is connected to the second node, and having a gate connected to the first node, a third transistor having nodes, one of which is connected to the first node, and another one of which is connected to a second power source that supplies a second voltage different from the first voltage, and having a gate connected to the second node, a fourth transistor having nodes, one of which is connected to the second node, and another one of which is connected to the second power source, and having a gate connected to the first node, a fifth transistor having nodes, one of which is connected to a first write-bit line, and another one of which is connected to the first node, and having a gate connected to a write-word line, a sixth transistor having nodes, one of which is connected to a second write-bit line with which the first write-bit line constitute a complementary bit line pair, and another one of which is connected to the second node, and having a gate connected to the write-word line, a seventh transistor having nodes, one of which is connected to the second power source, and having a gate connected to the second node, and an eighth transistor having nodes, one of which is connected to another one of the nodes of the seventh transistor, and another one of which is connected to a first read-bit line, and having a gate connected to a read-word line, the first write-bit line includes a first buried interconnect formed in a buried interconnect layer and extending in a first direction, and a first line formed in a first line layer located above the first to sixth transistors and extending in the first direction, the second write-bit line includes a second buried interconnect formed in the buried interconnect layer and extending in the first direction, and a second line formed in the first line layer and extending in the first direction.

According to the present disclosure, the first write-bit line includes a first buried interconnect formed in a buried interconnect layer, and a first line formed in the first line layer, and the second write-bit line includes a second buried interconnect formed in a buried interconnect layer, and a second line formed in the first line layer. That is, the first write-bit line and the second write-bit line are each formed in the buried interconnect layer and in the M1 line layer. Accordingly, the resistance values of the first and second write-bit lines can be reduced, and thus the semiconductor memory device can operate at a high speed and its writing characteristic can be improved. Further, the first and second write-bit lines are formed in each of the buried interconnect layer and the M1 line layer, and thus, the resistance values of the first and second write-bit lines can be reduced whereas the area of the semiconductor memory device is less increased. Accordingly, the semiconductor memory device can operate at a high speed and its writing characteristic can be improved whereas the area of the semiconductor memory device is less increased.

A third aspect of the present disclosure is a semiconductor memory device including a first sub memory array and a second sub memory array each comprising SRAM cells arranged in an array, wherein the first sub memory array includes a first bit line and a second bit line that constitute a complementary bit line pair, the second sub memory array includes a third bit line and a fourth bit line that constitute a complementary bit line pair, the first bit line includes a first buried interconnect formed in a buried interconnect layer and extending in a first direction, and a first line formed in a first line layer located above the buried interconnect layer and extending in the first direction, the second bit line includes a second buried interconnect formed in the buried interconnect layer and extending in the first direction, and a second line formed in the first line layer and extending in the first direction, the third bit line includes at least one of a third buried interconnect formed in the buried interconnect layer and extending in the first direction and a third line formed in the first line layer and extending in the first direction, and the fourth bit line includes at least one of a fourth buried interconnect formed in the buried interconnect layer and extended in the first direction and a fourth line formed in the first line layer and extended in the first direction.

According to the present disclosure, the first bit line in the first sub memory array includes a first buried interconnect formed in a buried interconnect layer, and a first line formed in the first line layer, and the second bit line includes a second buried interconnect formed in a buried interconnect layer, and a second line formed in the first line layer. That is, in the first sub memory array, the first bit line and the second bit line are each formed in the buried interconnect layer and in the M1 line layer. Accordingly, the resistance values of the first and second bit lines can be reduced, and thus the semiconductor memory device can operate at a high speed and its writing characteristic can be improved. Further, in the first sub memory array, the first and second bit lines are formed in each of the buried interconnect layer and the M1 line layer, and thus, the resistance values of the bit lines can be reduced whereas the area of the semiconductor memory device is less increased. Accordingly, the semiconductor memory device can operate at a high speed and its writing characteristic can be improved whereas the area of the semiconductor memory device is less increased.

According to the present disclosure, in the layout configuration of the SRAM cell where the bit lines are provided in the buried interconnect layer, the semiconductor memory device can operate at a high speed and its writing characteristic can be improved whereas the area of the semiconductor memory device is less increased.

### BRIEF DESCRIPTION OF THE DRAWINGS

FIG. 1 is a plan view showing an exemplary layout configuration of a 1-port SRAM cell of a first embodiment.

FIG. 2 is a cross-sectional view showing the exemplary layout configuration of the 1-port SRAM cell of the first embodiment.

FIG. 3 is a cross-sectional view showing the exemplary layout configuration of the 1-port SRAM cell of the first embodiment.

FIG. 4 is a circuit diagram showing a configuration of the 1-port SRAM cell of the first embodiment.

FIG. 5 is a plan view showing another exemplary layout configuration of the 1-port SRAM cell of the first embodiment.

FIG. 6 is a cross-sectional view showing another exemplary layout configuration of the 1-port SRAM cell of the first embodiment.

FIG. 7 is a plan view showing another exemplary layout configuration of the 1-port SRAM cell of the first embodiment.

FIG. 8 is a plan view showing an exemplary layout configuration of a 2-port SRAM cell of a second embodiment.

FIG. 9 is a circuit diagram showing the configuration of the 2-port SRAM cell of the second embodiment.

FIG. 10 is a plan view showing another exemplary layout configuration of the 2-port SRAM cell of the second embodiment.

FIG. 11 is a plan view showing another exemplary layout configuration of the 2-port SRAM cell of the second embodiment.

FIG. 12 is a plan view showing an exemplary layout configuration of a circuit block in a semiconductor memory device of a third embodiment.

FIG. 13 is a plan view showing another exemplary layout configuration of the circuit block in the semiconductor memory device of the third embodiment.

FIG. 14 is a plan view showing another exemplary layout configuration of the 1-port SRAM cell of the third embodiment.

FIG. 15 is a plan view showing another exemplary layout configuration of the 1-port SRAM cell of the third embodiment.

FIG. 16 is a plan view showing another exemplary layout configuration of the circuit block in the semiconductor memory device of the third embodiment.

### DETAILED DESCRIPTION

Embodiments will be described in detail with reference to the drawings. The following embodiments assume that a semiconductor memory device includes a plurality of memory SRAM cells (in the present specification, hereinafter simply referred to as cells as appropriate), and that at least part of the plurality of SRAM cells include, for example, a nanosheet FET. The nanosheet FET is an FET using a thin sheet (nanosheet) through which a current flows. The nanosheet is made of silicon, for example.

In the present disclosure, a semiconductor layer portion that is formed at both ends of the nanosheet and that constitutes a terminal to serve as the source or the drain of the nanosheet FET will be referred to as “pad.”

In the present disclosure, the SRAM cells include buried interconnect (BI) in a buried interconnect layer having lines buried in the substrate or shallow trench isolation (STI). In the following description, the line provided in the buried interconnect layer may be referred to as buried interconnect, and particularly, the power supply line provided in the buried interconnect layer may be referred to as buried power rail (BPR).

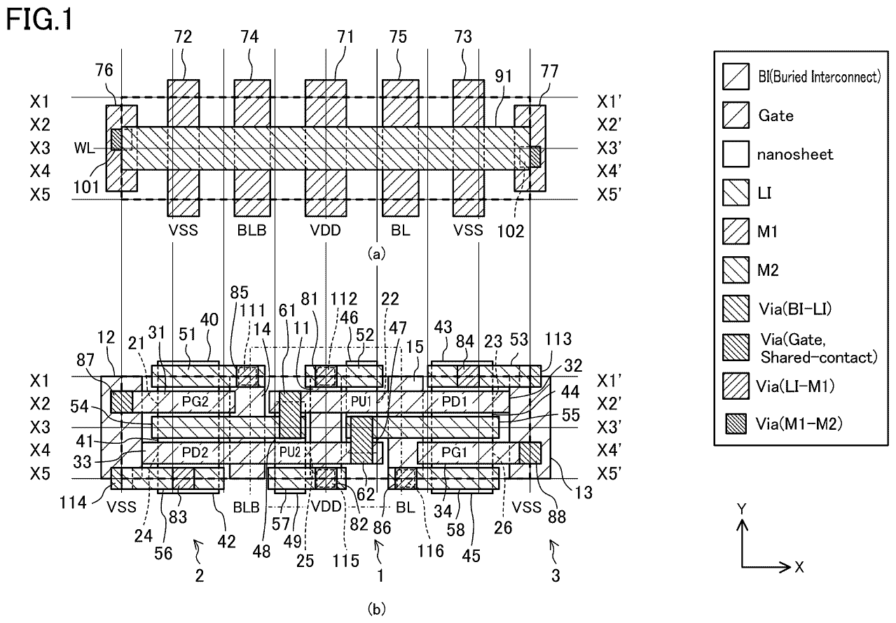

It should be noted that in the following description, the longitudinal direction of the figure in the plan view of FIG. 1 or the like is the Y-direction (corresponding to a first direction), the lateral direction is X-direction, and a direction perpendicular to the substrate surface is the Z-direction. The “VDD” represents a power supply voltage, a high voltage power source itself, or a high voltage power supply line, and the “VSS” represents a power supply voltage, a low voltage power supply itself, or a low voltage power supply line.

In the plan views and cross-sectional views referenced in the embodiments below, insulating films or the like may be omitted. In the plan views and cross-sectional views referenced in the embodiments below, the nanosheets and pads on both sides of the nanosheets may be illustrated in the form of a simplified linear shape. In the present disclosure, the expressions such as “the same size” indicating that the size and the like are the same encompasses a range of variation in manufacturing.

In the present disclosure, the source and drain of the transistor are referred to as “nodes” of the transistor where appropriate. That is, one of nodes of a transistor indicates a source or a drain of the transistor, and both nodes of a transistor indicate a source and a drain of the transistor.

In the following embodiments and modifications thereof, the same reference characters are used to represent equivalent elements, and the detailed explanation thereof will be omitted.

### First Embodiment

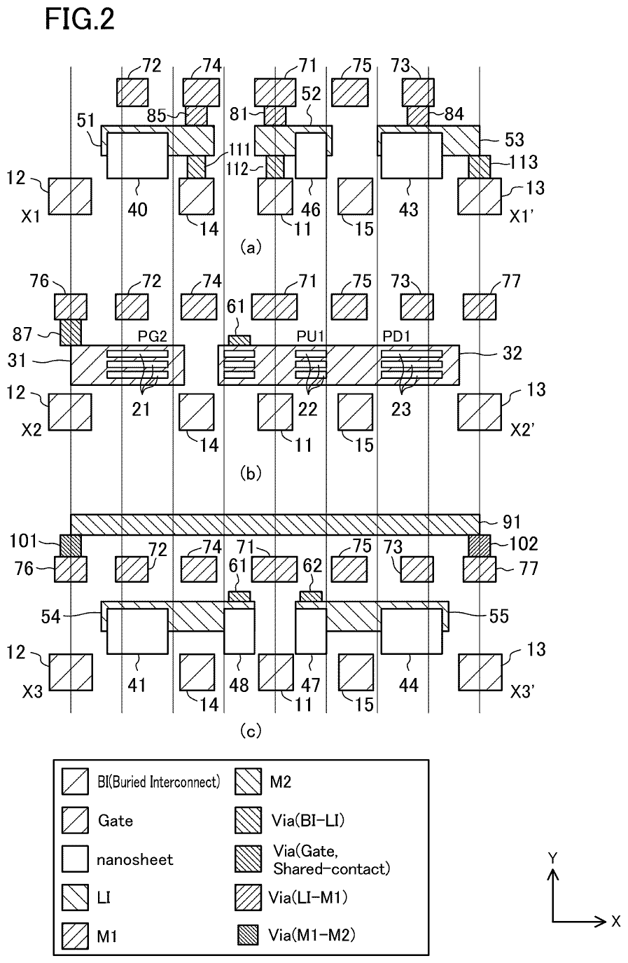

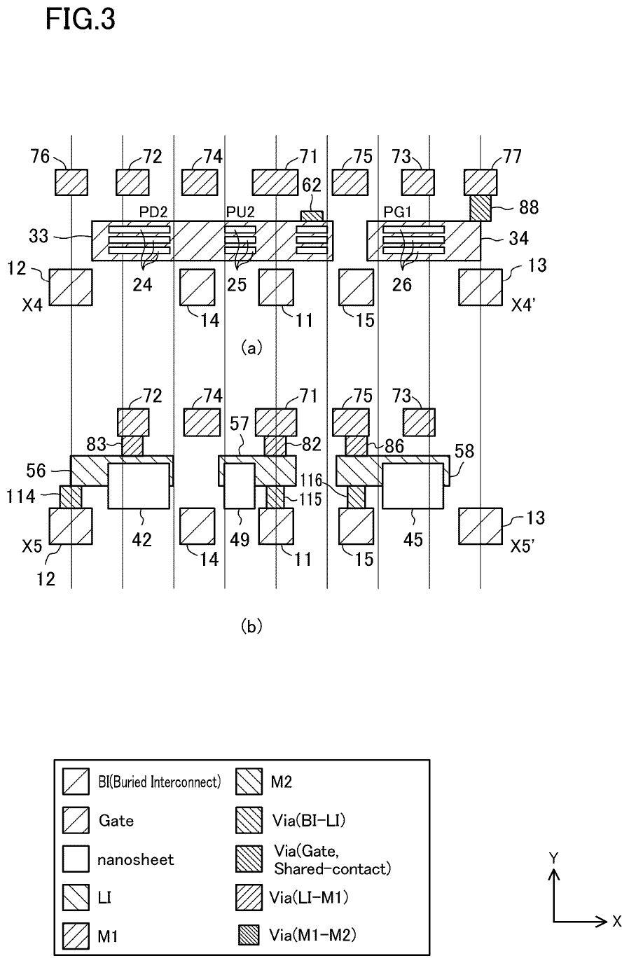

FIG. 1 to FIG. 3 each shows an exemplary layout configuration of a 1-port SRAM cell of a first embodiment. illustrations (a) and (b) of FIG. 1 are each plan view. illustrations (a) to (c) of FIG. 2 and illustrations (a) and (b) of FIG. 3 are each a cross-sectional view seen from a lateral direction in plan view. Specifically, the illustration (a) of FIG. 1 shows a cell upper part that is M1, M2 line layers, and the illustration (b) of FIG. 1 shows a cell lower part that is a layer below the M1, M2 line layers and includes a nanosheet FET. The illustration (a) of FIG. 2 is a cross-section taken along line X1-X1′. The illustration (b) of FIG. 2 is a cross-section taken along line X2-X2′. The illustration (c) of FIG. 2 is a cross-section taken along line X3-X3′. The illustration (a) of FIG. 3 is a cross-section taken along line X4-X4′. The illustration (b) of FIG. 3 is a cross-sectional view taken along line X5-X5′.

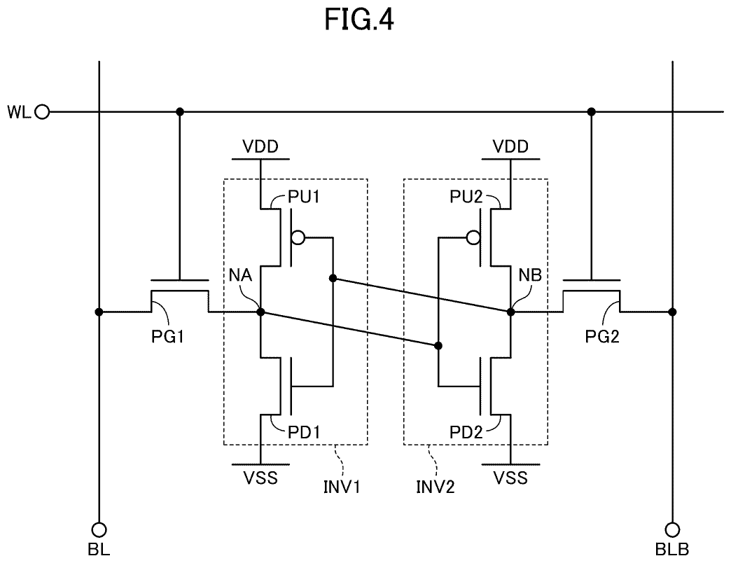

FIG. 4 is a circuit diagram showing a configuration of the 1-port SRAM cell of the first embodiment. As shown in FIG. 4, the 1-port SRAM cell includes a 1-port SRAM circuit consisting of load transistors PU1 and PU2, drive transistors PD1 and PD2, and access transistors PG1 and PG2. The load transistors PU1 and PU2 are each a P-type FET. The drive transistors PD1 and PD2 and the access transistors PG1 and PG2 are each an N-type FET.

The load transistor PU1 is provided between a power source VDD and a first node NA, and the drive transistor PD1 is provided between the first node NA and a power source VSS. The load transistor PU1 and the drive transistor PD1 have gates connected to a second node NB to configure an inverter INV1. The load transistor PU2 is provided between the power source VDD and a second node NB, and the drive transistor PD2 is provided between the second node NB and the power source VSS. The load transistor PU2 and the drive transistor PD2 have gates connected to the first node NA to configure an inverter INV2. That is, an output of one of the inverters is connected to an input of the other one of the inverters, thereby configuring a latch.

The access transistor PG1 is provided between a bit line BL and the first node NA, and the gate thereof is connected to a word line WL. The access transistor PG2 is provided between a bit line BLB and the second node NB, and has a gate connected to the word line WL. The bit lines BL and BLB constitute a complementary bit line pair.

In the 1-port SRAM circuit, if the bit lines BL and BLB constituting the complementary bit line pair are driven to a high level and a low level, respectively, and the word line WL is driven to a high level, the high level is written to the first node NA and the low level is written to the second node NB. In contrast, if the bit lines BL and BLB are driven to a low level and a high level, respectively, and the word line WL is driven to a high level, the low level is written to the first node NA and the high level is written to the second node NB. Then, if the word line WL is driven to a low level with the data being written to the first and second nodes NA and NB, a latch state is determined and the data written to the first and second nodes NA and NB is retained.

If the bit lines BL and BLB are pre-charged to a high level and the word line WL is driven to a high level, the state of each of the bit lines BL and BLB is determined according to the data written to the first and second nodes NA and NB, and thus data can be read out from the SRAM cell. Specifically, if the first node NA is at a high level and the second node NB is at a low level, the bit line BL is held at a high level and the bit line BLB is discharged to a low level. In contrast, if the first node NA is at a low level and the second node NB is at a high level, the bit line BL is discharged to a low level and the bit line BLB maintains a high level.

As described above, the 1-port SRAM cell controls the bit lines BL and BLB and the word line WL, thereby serving functions of writing data to the SRAM cell, retaining data, and reading out data from the SRAM cell.

In the following description, solid lines running longitudinally and laterally in the plan view of FIG. 1 and the like and solid lines running longitudinally in the cross-sectional view of FIG. 2 and the like show grids used for arranging components at the time of designing. The grids are spaced evenly in the X-direction, and also spaced evenly in the Y-direction. The space between the grids in the X-direction and those in the Y-direction may be the same or may be different. The intervals between the grids may be different in each layer. Further, the parts do not necessarily have to be arranged on the grids. However, for the sake of reduction in manufacturing-attributed variations, the parts are preferably arranged on the grids.

The dotted lines surrounding the cell in the plan view of FIG. 1 and the like indicate a cell frame of the 1-port SRAM cell (an outer edge of the 1-port SRAM cell). The 1-port SRAM cell is arranged so that its cell frame is contact with a cell frame of an adjacent cell in the X-direction or Y-direction.

In the plan view of FIG. 1 and the like, 1-port SRAM cells inverted in the X-direction are arranged on both sides of the 1-port SRAM cell in the X-direction. 1-port SRAM cells inverted in the Y-direction are arranged on both sides of the 1-port SRAM cell in the Y-direction.

As shown in the illustration (b) of FIG. 1, in the buried interconnect layer, buried power rails 11 to 13 and buried interconnects 14 and 15 extending in the Y-direction are formed over both upper and lower ends of the cell in the drawing. The buried power rail 11 is formed near the middle of the cell in the drawing, and the buried power rails 12 and 13 are formed on the left and right ends of the cell in the drawing. The buried power rail 11 supplies the power supply voltage VDD. The buried power rails 12 and 13 supply the power supply voltage VSS.

The buried interconnect 14 is formed between the buried power rails 11 and 12. Specifically, the buried interconnect 14 is formed between a nanosheet 24 (21) and a nanosheet 25, which will be described later, in a plan view. The buried interconnect 15 is formed between the buried power rails 11 and 13. Specifically, the buried interconnect 15 is formed between a nanosheet 22 and a nanosheet 23 (26), which will be described later, in a plan view. The buried interconnects 14 and 15 correspond to the bit lines BLB and BL, respectively.

The load transistors PU1 and PU2 are formed on an N-well 1. The access transistor PG2 and the drive transistor PD2 are formed on a P-type substrate 2. The drive transistor PD1 and the access transistor PG1 are formed on a P-type substrate 3.

As shown in the illustration (b) of FIG. 1, nanosheets 21 to 26 extending in the X-direction and the Y-direction are formed. The nanosheets 21 to 23 are arranged in the X-direction in the order of the nanosheets 21 to 23. The nanosheets 24 to 26 are arranged in the X-direction in the order of the nanosheets 24 to 26. The nanosheets 21 and 24 are arranged in the Y-direction. The nanosheets 23 and 26 are arranged in the Y-direction. The width of each of the nanosheets 21, 23, 24, 26 in the X-direction is twice the width of each of the nanosheets 22, and 25 in the X-direction.

The nanosheets 21 to 26 constitute channel parts of the access transistor PG2, the load transistor PU1, the drive transistor PD1, the drive transistor PD2, the load transistor PU2, and the access transistor PG1, respectively.

As shown in the illustration (b) of FIG. 2 and the illustration (a) of FIG. 3, the nanosheets 21 to 26 each consist of three semiconductor sheets (nanosheets). The nanosheets 21 to 26 are disposed so that the nanosheets constituting each of the nanosheets 21 to 26 overlap each other in a plan view and are spaced apart from one another in the Z-direction. That is, nanosheet FETs in the 1-port SRAM cells of this embodiment each includes three nanosheets.

As shown in the illustration (b) of FIG. 1, gate lines (Gate) 31 to 34 extend in the X-direction and the Z-direction. The gate lines 31 and 32 are arranged in the X-direction, and the gate lines 33 to 34 are arranged in the X-direction.

The gate line 31 overlaps the nanosheet 21 in a plan view. The gate line 32 overlaps the nanosheets 22 and 23 in a plan view. The gate line 33 overlaps the nanosheets 24 and 25 in a plan view. The gate line 34 overlaps the nanosheet 26 in a plan view.

The gate line 31 serves as the gate of the access transistor PG2. The gate line 32 serves as the gates of the load transistor PU1 and the drive transistor PD1. The gate line 33 serves as the gates of the drive transistor PD2 and the load transistor PU2. The gate line 34 serves as the gate of the access transistor PG1.

Pads 40 to 45 doped with an N-type semiconductor are formed at the upper end of the nanosheet 21 in the drawing; between the nanosheets 21 and 24; at the lower end of the nanosheet 24 in the drawing; at the upper end of the nanosheet 23 in the drawing; between the nanosheets 23 and 26; and at the lower end of the nanosheet 26 in the drawing, respectively. The pads 40 and 41 constitute a node of the access transistor PG2. The pads 41 and 42 constitute a node of the drive transistor PD2. The pads 43 and 44 constitute a node of the drive transistor PD1. The pads 44 and 45 constitute a node of the access transistor PG1.

Pads 46 to 49 doped with a P-type semiconductor are formed at the upper end of the nanosheet 22 in the drawing; at the lower end of the nanosheet 22 in the drawing; at the upper end of the nanosheet 25 in the drawing; and at the lower end of the nanosheet 25 in the drawing, respectively. The pads 46 and 47 constitute a node of the load transistor PU1. The pads 48 and 49 constitute a node of the load transistor PU2.

In a local interconnect layer, local interconnects (LIs) 51 to 58 extending in the X-direction are formed. The local interconnect 51 is connected with the pad 40. The local interconnect 52 is connected with the pad 46. The local interconnect 53 is connected with the pad 43. The local interconnect 54 is connected with the pads 41 and 48. The local interconnects 55 is connected with the pads 47 and 44. The local interconnect 56 is connected with the pad 42. The local interconnect 57 is connected with the pad 49. The local interconnect 58 is connected with the pad 45.

The local interconnect 51 is connected with the buried interconnect 14 through a contact (Via) 111. The local interconnect 52 is connected with the buried power rail 11 through a contact 112. The local interconnect 53 is connected with the buried power rail 13 through a contact 113. The local interconnect 56 is connected with the buried power rail 12 through a contact 114. The local interconnect 57 is connected with the buried power rail 11 through a contact 115. The local interconnect 58 is connected with the buried interconnect 15 through a contact 116.

The local interconnect 54 is connected with the gate line 32 through a shared-contact 61. The local interconnect 55 is connected with the gate line 33 through a shared-contact 62. The gate line 33, the local interconnect 55, and the shared-contact 62 correspond to a first node NA. The gate line 32, the local interconnect 54, and the shared-contact 61 correspond to a second node NB.

As shown in the illustration (b) of FIG. 1, in the M1 line layer, lines 71 to 75 extending in the Y-direction are formed over both upper and lower ends of the cell in the drawing. Further, lines 76 and 77 are formed. The line 71 supplies the power supply voltage VDD. The lines 72 and 73 supply the power supply voltage VSS. The lines 74 and 75 correspond to the bit lines BLB and BL, respectively. That is, in this embodiment, the buried interconnect 14 and the line 74 correspond to the bit line BLB, and the buried interconnect 15 and the line 75 correspond to the bit line BL.

The line 71 is connected with the local interconnect 52 through a contact (Via) 81, and connected with the local interconnect 57 through a contact 82. The line 72 is connected with the local interconnect 56 through the contact 83. The line 73 is connected with the local interconnect 53 through the contact 84. The line 74 is connected with the local interconnect 51 through the contact 85. The line 75 is connected with the local interconnect 58 through the contact 86. The line 76 is connected with the gate line 31 through a contact (Gate-contact) 87. The line 77 is connected with the gate line 34 through a contact 88.

A line 91 extending in the X-direction from the left end to the right end of the cell in the drawing is formed in the M2 line layer located above the M1 line layer. The line 91 corresponds to the word line WL. The line 91 is connected with the line 76 through a contact 101, and connected with the line 77 through a contact 102.

With the above configuration, in the load transistor PU1, the pad 46 is connected to the buried power rail 11 and the line 71 that supply the power supply voltage VDD, the pad 47 is connected to the local interconnect 55 (first node NA), and the gate line 32 is connected to the shared-contact 61 (second node NB). In the load transistor PU2, the pad 49 is connected to the buried power rail 11 and the line 71 that supply the power supply voltage VDD, the pad 48 is connected to the local interconnect 54 (second node NB), and the gate line 33 is connected to the shared-contact 62 (first node NA). In the drive transistor PD1, the pad 44 is connected to the local interconnect 55 (first node NA), the pad 43 is connected to the buried power rail 13 and the line 73 that supply the power supply voltage VSS, and the gate line 32 is connected to the shared-contact 61 (second node NB). In the drive transistor PD2, the pad 41 is connected to the local interconnect 54 (second node NB), the pad 42 is connected to the buried power rail 12 and the line 72 that supply the power supply voltage VSS, and the gate line 33 is connected to the shared-contact 62 (first node NA). In the access transistor PG1, the pad 45 is connected to the buried interconnect 15 and line 75 (bit line BL), the pad 44 is connected to the local interconnect 55 (first node NA), and the gate line 34 is connected to the line 91 (word line WL). In the access transistor PG2, the pad 40 is connected to the buried interconnect 14 and line 74 (bit line BLB), the pad 41 is connected to the local interconnect 54 (second node NB), and the gate line 31 is connected to the line 91 (word line WL). The buried interconnects 14 and 15 are formed in the buried interconnect layer so as to extend in the Y-direction, and the lines 74 and 75 are formed in the M1 line layer located above the buried interconnect layer so as to extend in the Y-direction.

That is, the buried interconnect 15 and the line 75 corresponding to the bit line BL are formed in the buried interconnect layer and the M1 line layer, respectively, and the buried interconnect 14 and the line 74 corresponding to the bit line BLB are formed in the buried interconnect layer and the M1 line layer, respectively. Accordingly, the resistance values of the bit lines BL and BLB can be reduced, and thus the semiconductor memory device can operate at a high speed and its writing characteristic can be improved.

If each of the bit lines BL and BLB is formed in only any one of the buried interconnect layer and the M1 line layer, the resistance values of the bit lines BL and BLB can be reduced with the bit lines BL and BLB each having a wider line width, but the area of the semiconductor memory device is increased. To deal with this problem, in this embodiment, the bit lines BL and BLB are formed in each of the buried interconnect layer and the M1 line layer, and thus, the resistance values of the bit lines BL and BLB can be reduced whereas the area of the semiconductor memory device is less increased.

Accordingly, in the layout configuration of the SRAM cell where the bit lines are provided in the buried interconnect layer, the semiconductor memory device can operate at a high speed and its writing characteristic can be improved whereas the area of the semiconductor memory device is less increased.

The lines in the buried interconnect layer can be arranged in only a region where no transistor is arranged, but the lines in the M1 line layer have no such a restriction on the arrangement. Accordingly, by each of the bit lines BL and BLB being provided in the buried interconnect layer and the M1 line layer, the degree of freedom in designing the line positions and line widths of the lines 74 and 75 increases, and the performance and power consumption of the SRAM cells can be optimized.

The buried power rail 11 and the line 71 that supply the power supply voltage VDD are formed in the buried interconnect layer and the M1 line layer, respectively. The buried power rail 12 (13) and the line 72 (73) that supply the power supply voltage VSS are formed in the buried interconnect layer and the M1 line layer, respectively. Accordingly, the power source to the SRAM cells can be enhanced, and thus the stability of the operation of the semiconductor memory device can be improved.

As described above, the lines in the buried interconnect layer can be arranged in only a region where no transistor is arranged, but the lines in the M1 line layer have no such a restriction on the arrangement. Accordingly, by the lines that supply the power supply voltage being provided in each of the buried interconnect layer and the M1 line layer, the degree of freedom in designing the line positions and line widths of the lines 71 to 73 increases, and the performance of the SRAM cells can be optimized.

The width of each of the nanosheets 21, 23, 24, 26 in the X-direction is twice the width of each of the nanosheets 22 and 25 in the X-direction, but is not limited to this width. The width of each of the nanosheets 21 to 26 (i.e., gate width of each transistor) in the X-direction may be determined in consideration of the operational stability and the like of the 1-port SRAM circuit.

### Modification 1

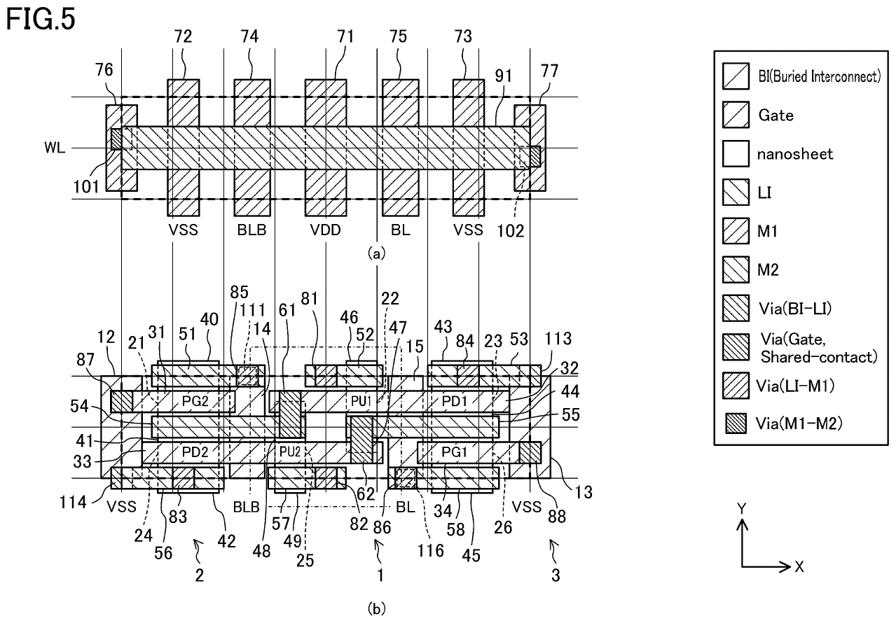

FIG. 5 is a plan view showing another exemplary layout configuration of the 1-port SRAM cell of the first embodiment. Specifically, an illustration (a) of FIG. 5 shows a cell upper part, and an illustration (b) of FIG. 5 shows a cell lower part. In FIG. 5, as compared with in FIG. 1, the buried power rail 11 is omitted.

As shown in the illustration (b) of FIG. 5, the space between the nanosheets 22 and 25 in the X-direction is narrower than the space between other nanosheets adjacent to each other in the X-direction (e.g., the space between the nanosheets 22 and 23 in the X-direction). Thus, it is not easy to arrange the buried power rail 11 between the nanosheets 22 and 25. Accordingly, by omitting the buried power rail 11, it is easier to manufacture the semiconductor memory device.

In addition, the advantages similar to those of FIG. 1 can be obtained.

### Modification 2

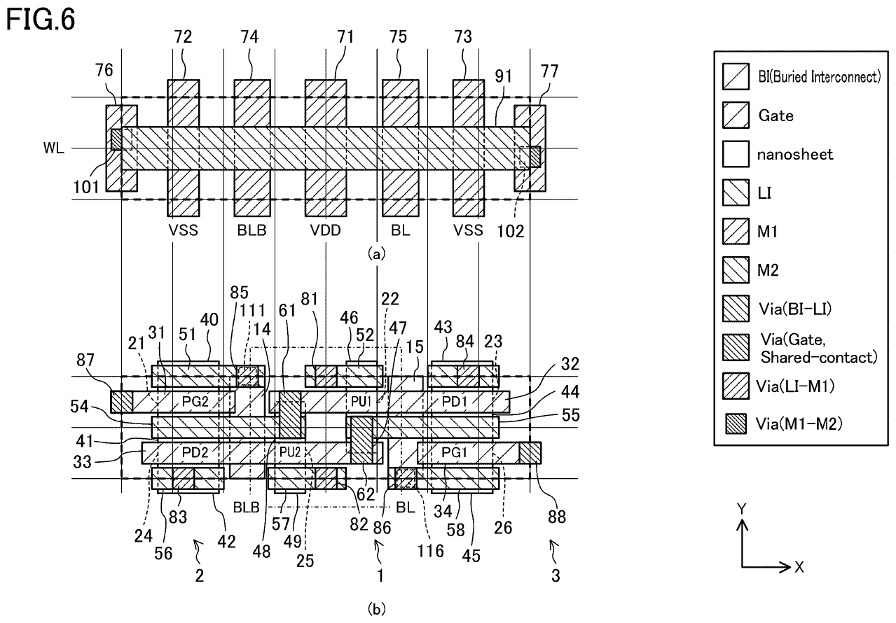

FIG. 6 is a plan view showing another exemplary layout configuration of the 1-port SRAM cell of the first embodiment. Specifically, an illustration of (a) of FIG. 6 shows a cell upper part, and an illustration of (b) of FIG. 6 shows a cell lower part. In FIG. 6, as compared with in FIG. 5, the buried power rails 12 and 13 are omitted.

According to Modification 2, the advantages similar to those of FIG. 5 can be obtained.

### Modification 3

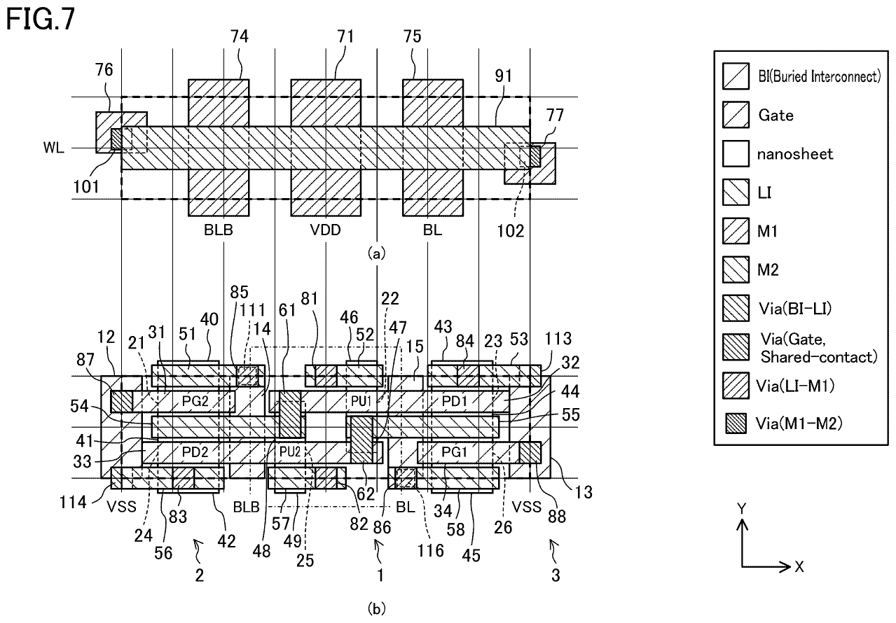

FIG. 7 is a plan view showing another exemplary layout configuration of the 1-port SRAM cell of the first embodiment. Specifically, an illustration (a) of FIG. 7 shows a cell upper part, and an illustration (b) of FIG. 7 shows a cell lower part. In FIG. 7, as compared with FIG. 5, the lines 72 and 73 are omitted, and the lines 71, 74, and 75 have wider line widths. The lines 71, 74, and 75 have line widths wider than those of the buried interconnects 14 and 15.

As shown in the illustration (a) of FIG. 7, by omitting the lines 72 and 73, the line widths of the lines 74 and 75 can be widened. Accordingly, the resistance values of the bit lines BL and BLB can be reduced, and thus the semiconductor memory device can operate at a high speed and its writing characteristic can be improved.

By omitting the lines 72 and 73, the line width of the line 71 can be widened. Accordingly, the resistance values of the power rails that supply the power supply voltage VDD can be reduced, and thus the power source to the SRAM cells can be enhanced, and the stability of the operation of the semiconductor memory device can be improved.

By omitting the lines 72 and 73, the degree of freedom in designing the line positions and line widths of the lines 71 to 73 increases, and the performance of the SRAM cells can be optimized.

In addition, the advantages similar to those of FIG. 5 can be obtained.

### Second Embodiment

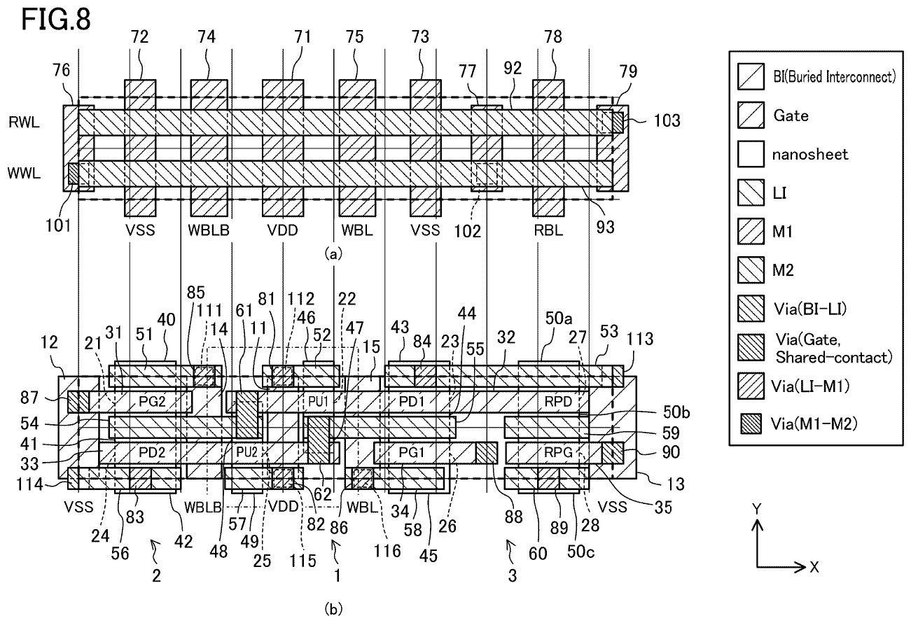

FIG. 8 is a plan view showing an exemplary layout configuration of a 2-port SRAM cell of the second embodiment. Specifically, an illustration (a) of FIG. 8 shows a cell lower part, and an illustration (b) of FIG. 8 shows a cell upper part.

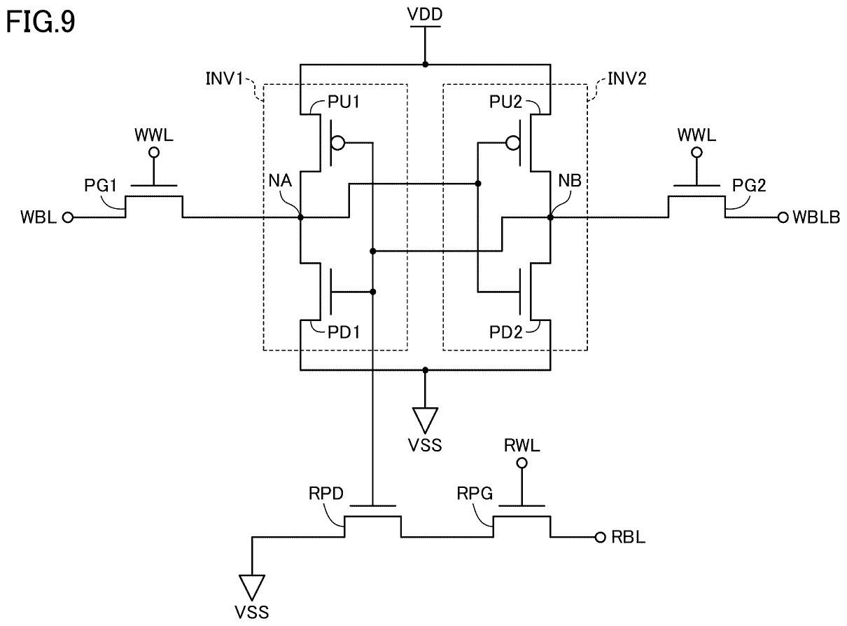

FIG. 9 is a circuit diagram showing a configuration of the 2-port SRAM cell of FIG. 8. As shown in FIG. 9, the 2-port SRAM cell includes a 2-port memory cell circuit consisting of load transistors PU1 and PU2, drive transistors PD1 and PD2, access transistors PG1 and PG2, a read drive transistor RPD, and a read access transistor RPG. The load transistors PU1 and PU2 are each a P-type FET, and the drive transistors PD1 and PD2, the access transistors PG1 and PG2, the read drive transistor RPD, and the read access transistor RPG are each an N-type FET.

The load transistor PU1 is provided between a power supply voltage VDD and a first node NA, and the drive transistor PD1 is provided between the first node NA and a power source VSS. The load transistor PU1 and the drive transistor PD1 have gates connected to a second node NB to configure an inverter INV1. The load transistor PU2 is provided between the power supply voltage VDD and the second node NB, and the drive transistor PD2 is provided between the second node NB and the power source VSS. The load transistor PU2 and the drive transistor PD2 have gates connected to the first node NA to configure an inverter INV2. That is, an output of one of the inverters is connected to an input of the other one of the inverters, thereby configuring a latch.

The access transistor PG1 is provided between a write-bit line WBL and the first node NA, and has a gate connected to a write-word line WWL. The access transistor PG2 is provided between a write-bit line WBLB and the second node NB, and has a gate connected to a write-word line WWL. The write-bit lines WBL and WBLB constitute a complementary write-bit line pair.

The read drive transistor RPD has a source connected to the power source VSS, a gate connected to the second node NB, and a drain connected to the source of the read access transistor RPG.

The read access transistor RPG has a gate connected to a read-word line RWL and a drain connected to a read-bit line RBL.

In the memory cell circuit of FIG. 9, if the write-bit lines WBL and WBLB constituting the complementary write-bit line pair are driven to a high level and a low level, respectively, and the write-word line WWL is driven to a high level, the high level is written to the first node NA and the low level is written to the second node NB. In contrast, if the write-bit lines WBL and WBLB are driven to a low level and a high level, respectively, and the write-word line WWL is driven to a high level, the low level is written to the first node NA and the high level is written to the second node NB. Then, if the write-word line WWL driven to a low level with the data being written to the first and the second nodes NA and NB, a latch state is determined and the data written to the first and the second nodes NA and NB is retained.

If the read-bit line RBL is pre-charged to a high level, and the read-word line RWL driven to a high level, the state of the read-bit line RBL is determined according to the data written to the second node NB, and thus data can be read out from the memory cell. Specifically, if the second node NB is at a high level, the read-bit line RBL is discharged to a low level. In contrast, if the second node NB is at a low level, the read-bit line RBL maintains a high level.

As described above, the 2-port SRAM cell controls the write-bit lines WBL and WBLB, the read-bit line RBL, the write-word line WWL, and the read-word line RWL, thereby serving functions of writing data to and retaining data in the 2-port SRAM cell, and reading out data from the 2-port SRAM cell.

As compared with FIG. 1, the 2-port SRAM cell of FIG. 8 includes the read drive transistor RPD and the read access transistor RPG on the right side of the drawing.

Specifically, as shown in FIG. 8, nanosheets 27 and 28 are formed on the right side of the nanosheets 23 and 26 in the drawing, respectively. The nanosheets 27 and 28 constitute channel parts of the read drive transistor RPD and the read access transistor RPG, respectively. The nanosheets 27 and 28 are arranged in the Y-direction. The width of each of the nanosheets 27 and 28 in the X-direction is twice the width of each of the nanosheets 22, and 25 in the X-direction.

The gate line 35 extending in the X-direction and the Z-direction is formed on the right side of the gate line 34 in the drawing. The gate line 32 serves as a gate of the read drive transistor RPD and the gate line 35 serves as a gate of the read access transistor RPG.

Pads to 50a to 50c doped with an N-type impurity are formed at the upper end of the nanosheet 27 in the drawing; between the nanosheets 27 and 28; and at the lower end of the nanosheet 28 in the drawing, respectively. The pads 50a and 50b constitute a node of the read drive transistor RPD. The pads 50b and 50c constitute a node of the read access transistor RPG.

In the local interconnect layer, local interconnects 59 and 60 extending in the X-direction are formed. The local interconnects 53 is connected with the pad 50a. The local interconnects 59 is connected with the pad 50b. The local interconnects 60 is connected with the pad 50c.

In the M1 line layer, a line 78 extending in the Y-direction is formed. Further, a line 79 is formed. The line 78 corresponds to the read-bit line RBL. The line 78 is connected with the local interconnect 60 through a contact 89. The line 79 is connected with the gate line 35 through a contact 90.

In the M2 line layer, lines 92 and 93 extending in the X-direction are formed. The line 92 corresponds to the read-word line RWL, and the line 93 corresponds to the write-word line WWL. The line 92 is connected with the line 79 through a contact 103. The line 93 is connected with the line 76 through a contact 101. The line 93 is connected with the line 77 through a contact 102.

In FIG. 8, the buried interconnect 14 and the line 74 correspond to the write-bit lines WBLB, and the buried interconnect 15 and the line 75 correspond to the write-bit lines WBL.

With the above configuration, in the load transistor PU1, the pad 46 is connected to the buried power rail 11 and the line 71 that supply the power supply voltage VDD, the pad 47 is connected to the local interconnect 55 (first node NA), and the gate line 32 is connected to the shared-contact 61 (second node NB). In the load transistor PU2, the pad 49 is connected to the buried power rail 11 and the line 71 that supply the power supply voltage VDD, the pad 48 is connected to the local interconnect 54 (second node NB), and the gate line 33 is connected to the shared-contact 62 (first node NA). In the drive transistor PD1, the pad 44 is connected to the local interconnect 55 (first node NA), the pad 43 is connected to the buried power rail 13 and the line 73 that supply the power supply voltage VSS, and the gate line 32 is connected to the shared-contact 61 (second node NB). In the drive transistor PD2, the pad 41 is connected to the local interconnect 54 (second node NB), the pad 42 is connected to the buried power rail 12 and the line 72 that supply the power supply voltage VSS, and the gate line 33 is connected to the shared-contact 62 (first node NA). In the access transistor PG1, the pad 45 is connected to the buried interconnect 15 and line 75 (write-bit line WBL), the pad 44 is connected to the local interconnect 55 (first node NA), and the gate line 34 is connected to the line 93 (write-word line WWL). In the access transistor PG2, the pad 40 is connected to the buried interconnect 14 and the line 74 (write-bit line WBLB), the pad 41 is connected to the local interconnect 54 (second node NB), and the gate line 31 is connected to the line 93 (write-word line WWL). In the read drive transistor RPD, the pad 50a is connected to the buried power rail 13 and the line 73, and the gate is connected to the shared-contact 61 (second node NB). In the read access transistor RPG, the pad 50b is shared with the read drive transistor RPD, and the pad 50c is connected to the line 78 (read-bit line RBL), and the gate is connected to the line 92 (read-word line RWL). The buried interconnects 14 and 15 are formed in the buried interconnect layer so as to extend in the Y-direction, and the lines 74 and 75 are formed in the M1 line layer located above the buried interconnect layer so as to extend in the Y-direction.

That is, the buried interconnect 15 and the line 75 corresponding to the write-bit line WBL are formed in the buried interconnect layer and the M1 line layer, respectively, and the buried interconnect 14 and the line 74 corresponding to the write-bit line WBLB are formed in the buried interconnect layer and the M1 line layer, respectively. Accordingly, the resistance values of the write-bit lines WBL and WBLB can be reduced, and thus the semiconductor memory device can operate at a high speed and its writing characteristic can be improved.

If each of the write-bit lines WBL and WBLB is formed in only any one of the buried interconnect layer and the M1 line layer, the resistance values of the write-bit lines WBL and WBLB can be reduced with the bit lines BL and BLB each having a wider line width, but the area of the semiconductor memory device is increased. To deal with this problem, in this embodiment, the write-bit lines WBL and WBLB are formed in each of the buried interconnect layer and the M1 line layer, and thus, the resistance values of the write-bit lines WBL and WBLB can be reduced whereas the area of the semiconductor memory device is less increased.

Accordingly, in the layout configuration of the SRAM cell where the bit lines are provided in the buried interconnect layer, the semiconductor memory device can operate at a high speed and its writing characteristic can be improved whereas the area of the semiconductor memory device is less increased.

The lines in the buried interconnect layer can be arranged in only a region where no transistor is arranged, but the lines in the M1 line layer have no such a restriction on the arrangement. Accordingly, by each of the write-bit lines WBL and WBLB being provided in the buried interconnect layer and the M1 line layer, the degree of freedom in designing the line positions and line widths of the lines 74 and 75 increases, and the performance of the SRAM cells can be optimized.

The buried power rail 11 and the line 71 that supply the power supply voltage VDD are formed in the buried interconnect layer and the M1 line layer, respectively. The buried power rail 12 (13) and the line 72 (73) that supply the power supply voltage VSS are formed in the buried interconnect layer and the M1 line layer, respectively. Accordingly, the power source to the SRAM cells can be enhanced, and thus the stability of the operation of the semiconductor memory device can be improved.

In FIG. 8, the buried power rail 11 may be omitted. The buried power rails 12 and 13 may be omitted.

The width of each of the nanosheets 21, 23, 24, 26, 27, and 28 in the X-direction is twice the width of each of the nanosheets 22 and 25 in the X-direction, but is not limited to this width. The width of each of the nanosheets 21 to 28 (i.e., gate width of each transistor) in the X-direction may be determined in consideration of the operational stability of the 2-port SRAM circuit.

### Modification 1

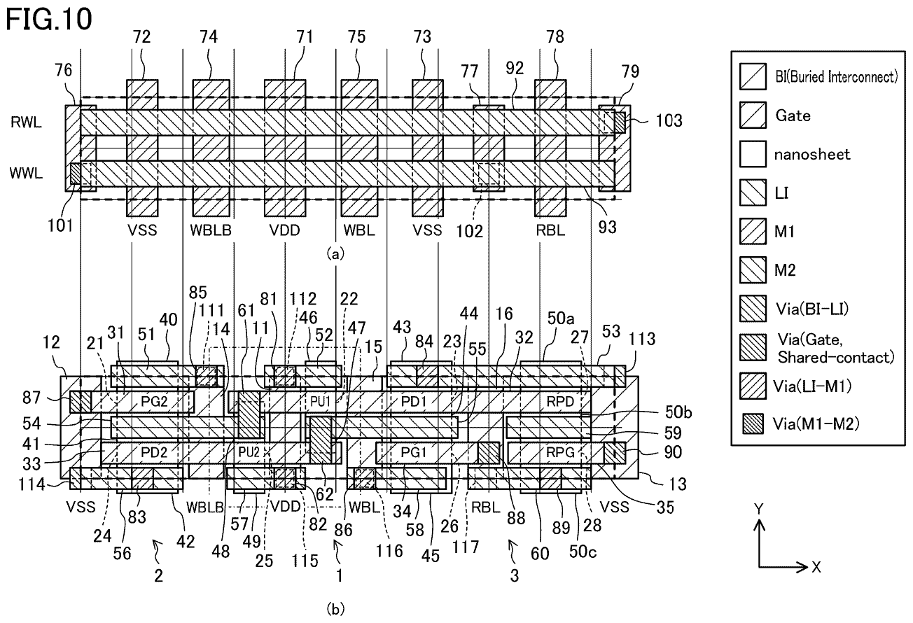

FIG. 10 is a plan view showing another exemplary layout configuration of the 2-port SRAM cell of the second embodiment. Specifically, an illustration (a) of FIG. 10 shows a cell upper part, and an illustration (b) of FIG. 10 shows a cell lower part. In FIG. 10, as compared with FIG. 8, a buried interconnect 16 is formed in the buried interconnect layer.

Specifically, the buried interconnect 16 is formed between a nanosheet 23 (26) and a nanosheet 27 (28) in a plan view. The buried interconnect 16 is connected with the local interconnect 60 through a contact 117. The buried interconnect 16 corresponds to the read-bit line RBL.

In this modification, the buried interconnect 16 and the line 78 corresponding to the read-bit line RBL are formed in the buried interconnect layer and the M1 line layer, respectively. Accordingly, the resistance value of the read-bit line RBL can be reduced, and thus the reading characteristic of the semiconductor memory device can be improved.

If the read-bit line RBL is formed in only any one of the buried interconnect layer and the M1 line layer, the resistance value of the read-bit line RBL can be reduced with the read-bit line RBL having a wider line width, but the area of the semiconductor memory device is increased. To deal with this problem, in this embodiment, the read-bit line RBL is formed in each of the buried interconnect layer and the M1 line layer, and thus, the resistance value of the read-bit line RBL can be reduced whereas the area of the semiconductor memory device is less increased.

Accordingly, in the layout configuration of the SRAM cell where the bit lines are provided in the buried interconnect layer, the reading characteristic of the semiconductor memory device can be improved whereas the area of the semiconductor memory device is less increased.

In addition, the advantages similar to those of FIG. 8 can be obtained.

### Modification 2

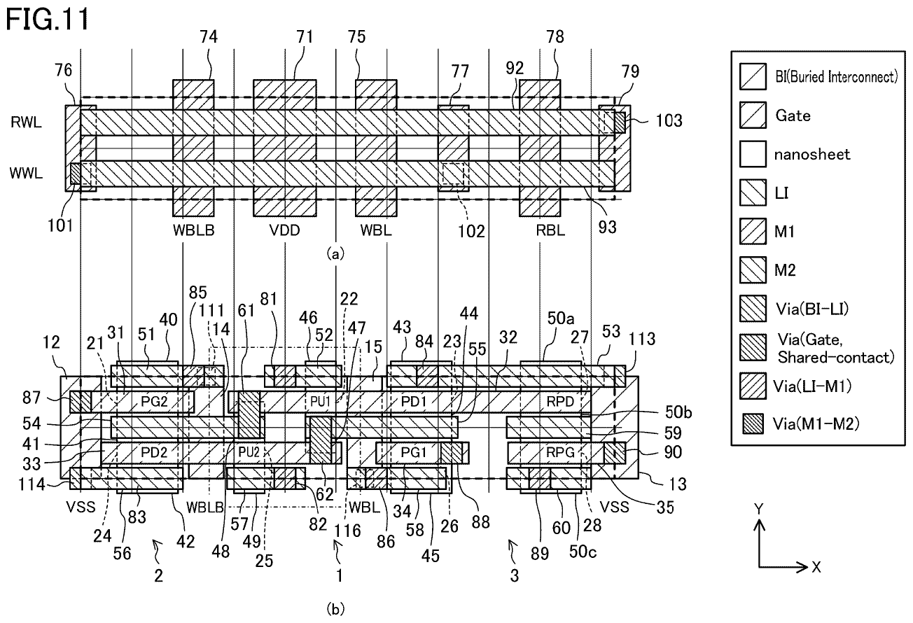

FIG. 11 is a plan view showing another exemplary layout configuration of the 2-port SRAM cell of the second embodiment. Specifically, an illustration (a) of FIG. 11 shows a cell upper part, and an illustration (b) of FIG. 11 shows a cell lower part. In FIG. 11, as compared with FIG. 8, a buried power rail 11 and lines 72 and 73 are omitted. The lines 71, 74, 75, 78 has a wider line width. The lines 71, 74, 75, and 78 has a line width wider than those of the buried interconnects 14 and 15.

As shown in the illustration (a) of FIG. 11, by omitting the lines 72 and 73, the line widths of the lines 74, 75, and 78 can be widened. Accordingly, the resistance values of the write-bit lines WBL and WBLB and the read-bit line RBL can be reduced, and thus the semiconductor memory device can operate at a high speed and its writing characteristic can be improved.

By omitting the lines 72 and 73, the line width of the line 71 can be widened. Accordingly, the resistance values of the power rails that supply the power supply voltage VDD can be reduced, and thus the power source to the SRAM cells can be enhanced, and the stability of the operation of the semiconductor memory device can be improved.

By omitting the lines 72 and 73, the degree of freedom in designing the line positions and line widths of the lines 71, 74, 75, and 78 increases, and the performance of the SRAM cells can be optimized.

As shown in the illustration (b) of FIG. 11, the space between the nanosheets 22 and 25 in the X-direction is narrower than the space between other nanosheets adjacent to each other in the X-direction (e.g., the space between the nanosheets 22 and 23 in the X-direction). Thus, it is not easy to arrange the buried power rail 11 between the nanosheets 22 and 25. Accordingly, by omitting the buried power rail 11, it is easier to manufacture the semiconductor memory device.

In addition, the advantages similar to those of FIG. 8 can be obtained.

### Third Embodiment

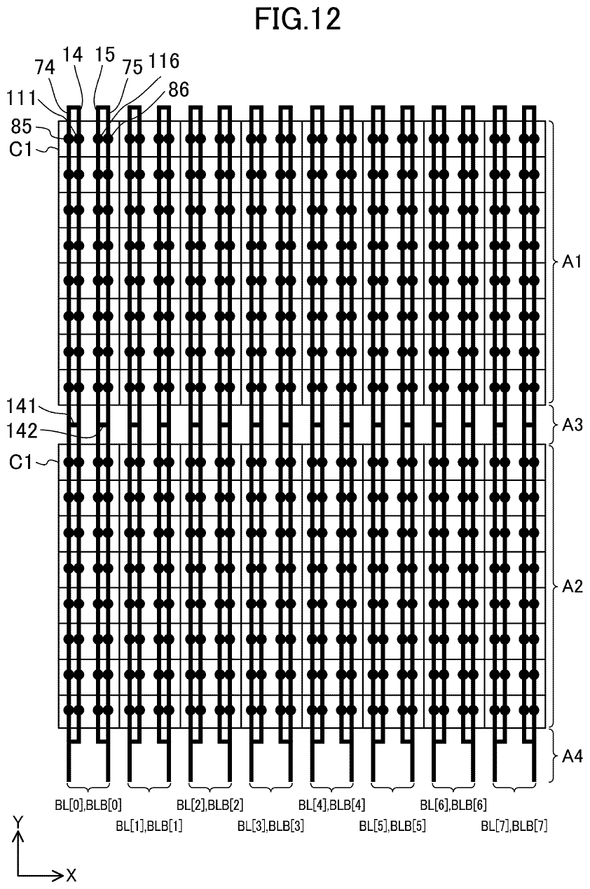

FIG. 12 is a plan view showing an exemplary layout configuration of a circuit block in a semiconductor memory device of a third embodiment. FIG. 12 schematically shows an arrangement of the cells, an arrangement of the buried interconnects 14 and 15 in the buried interconnect layer, an arrangement of contacts 111 and 116 connected to the buried interconnects 14 and 15, an arrangement of the lines 74 and 75 in the M1 line layer, and an arrangement of contacts 85 and 86 connected to the lines 74 and 75.

As shown in FIG. 12, a semiconductor memory device of the third embodiment includes sub memory arrays A1 and A2 arranged in the Y-direction. Between the sub memory arrays A1 and A2, a region A3 is formed. Below the sub memory array A2 in the drawing, a region A4 is formed.

The sub memory arrays A1 and A2 each include a plurality of SRAM cells C1. In FIG. 12, the sub memory arrays A1 and A2 each include eight memory SRAM cells C1 in the X-direction and eight SRAM cells C1 in the Y-direction. The SRAM cell C1 contains any of the SRAM cells of FIG. 1, FIG. 5, FIG. 6, FIG. 7, FIG. 8, FIG. 10, and FIG. 11.

The regions A3 and A4 contain cells including well taps and local amplifiers.

As shown in FIG. 12, in the sub memory arrays A1 and A2, the SRAM cells C1 adjacent to each other in the Y-direction have the buried interconnects 14 and 15 and the lines 74 and 75 connected to each other. In the region A3, the buried interconnects 14 and 15 and the lines 74 and 75 in the SRAM cells C1 at the lower end of the sub memory array A1 in the drawing are connected to the buried interconnects 14 and 15 and lines 74 and 75 in the SRAM cells C1 at the upper end of the sub memory array A2 in the drawing, respectively. That is, in the semiconductor memory device of this embodiment, the buried interconnects 14 and 15 and the lines 74 and 75 are each formed as a line extending in the Y-direction. Then, through the buried interconnects 14 and 15 and the lines 74 and 75, signals are written into each SRAM cell C1.

In a region outside the sub memory arrays A1 and A2, the buried interconnect 14 and the line 74 are connected and the buried interconnect 15 and the line 75 are connected. For example, in FIG. 12, in the region A3, the buried interconnect 14 and the line 74 are connected through a line or a contact schematically represented by 141, and the buried interconnect 15 and the line 75 are connected through a line or a contact schematically represented by 142.

As described above, in the SRAM cell C1, the buried interconnect 14 and the line 74 are connected and the buried interconnect 15 and the line 75 are connected. In the region (e.g., region A3) other than the sub memory arrays A1 and A2, the buried interconnect 14 and the line 74 are connected and the buried interconnect 15 and the line 75 are connected. Accordingly, the resistance values of the bit lines BL and BLB can be reduced, and thus the semiconductor memory device can operate at a high speed and its writing characteristic can be improved.

### Modification 1

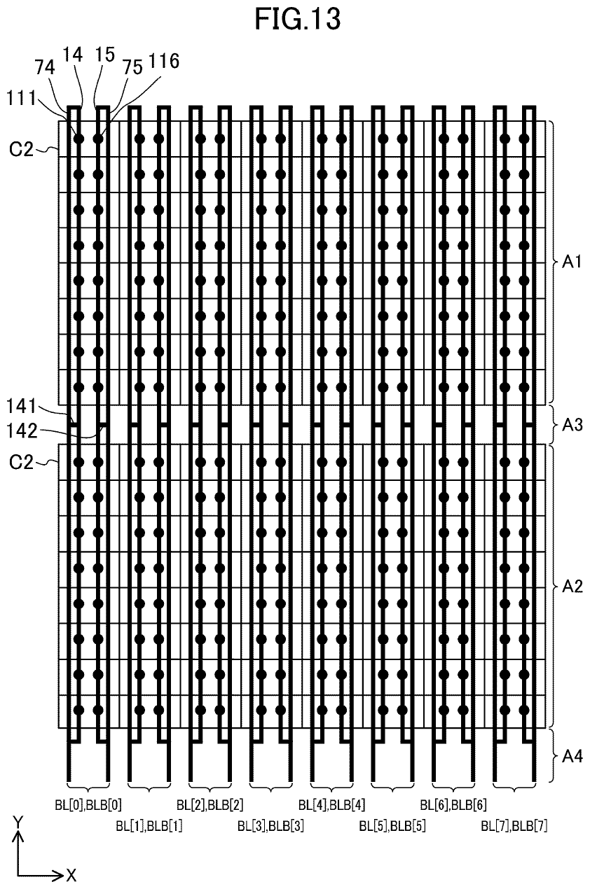

FIG. 13 is a plan view showing another exemplary layout configuration of the circuit block in the semiconductor memory device of the third embodiment. In FIG. 13, as compared with FIG. 12, SRAM cells C2 are arranged instead of the SRAM cells C1 in the sub memory arrays A1 and A2.

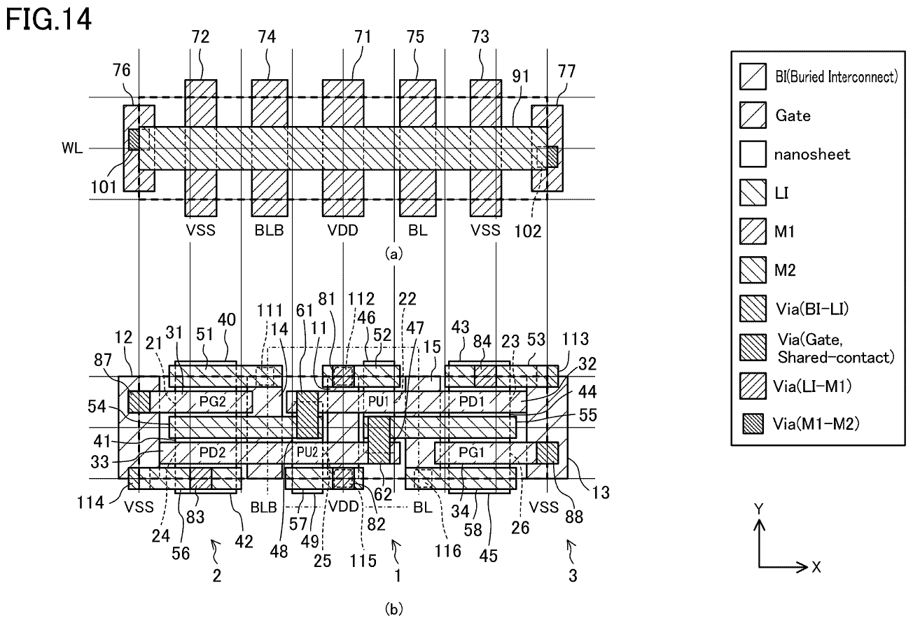

FIG. 14 is a plan view showing another exemplary layout configuration of the 1-port SRAM cell of the third embodiment. Specifically, an illustration (a) of FIG. 14 shows a cell upper part, and an illustration (b) of FIG. 14 shows a cell lower part. The SRAM cell shown in FIG. 14 is arranged as the SRAM cell C2 in FIG. 13. In FIG. 14, as compared with FIG. 1, the contacts 85 and 86 connected to the lines 74 and 75, respectively, are omitted. That is, in each SRAM cell C2 shown in FIG. 13 and FIG. 14, the lines 74 and 75 are not connected with the access transistors PG2 and PG1.

In FIG. 13 and FIG. 14, in the SRAM cell C2, the buried interconnect 14 and the line 74 are not connected through the local interconnect 51, and the buried interconnect 15 and the line 75 are not connected through the local interconnect 58; but in the region (e.g., region A3) outside the sub memory arrays A1 and A2, the buried interconnect 14 and the line 74 are connected and the buried interconnect 15 and the line 75 are connected. Accordingly, the resistance values of the bit lines BL and BLB can be reduced, and thus the semiconductor memory device can operate at a high speed and its writing characteristic can be improved.

The lines 74 and 75 do not have to be connected to the transistors in the SRAM cell C2, and thus the degree of freedom in designing the lines 74 and 75 is improved.

In this modification, the SRAM cells C2 are arranged in the sub memory arrays A1 and A2, but the SRAM cells C1 may be arranged instead of the SRAM cells C2 in a part of the sub memory arrays A1 and A2.

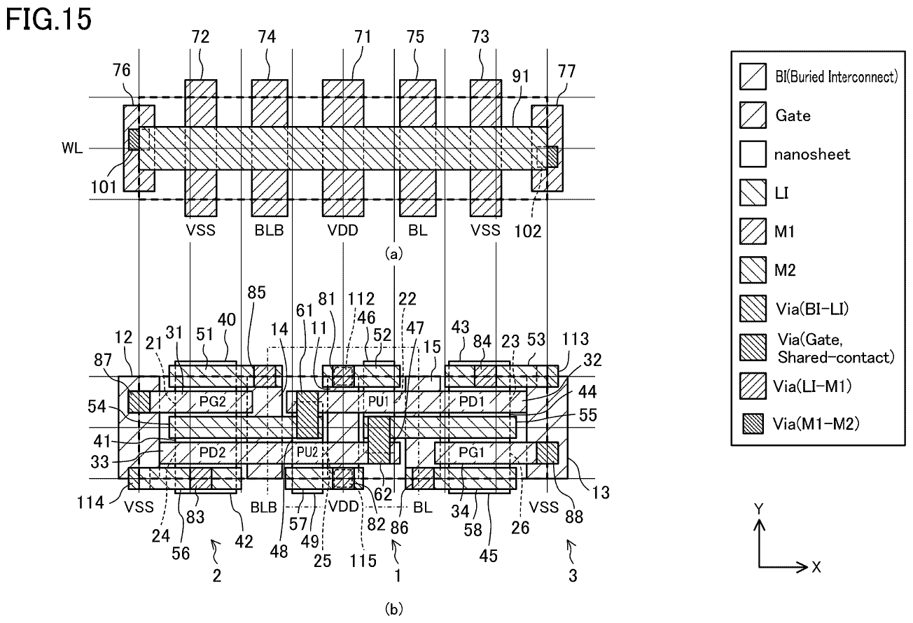

FIG. 15 is a plan view showing another exemplary layout configuration of the 1-port SRAM cell of the third embodiment. Specifically, an illustration (a) of FIG. 15 shows a cell upper part, and an illustration (b) of FIG. 15 shows a cell lower part. In FIG. 15, as compared with FIG. 1, the contacts 111 and 116 connected to the buried interconnects 14 and 15, respectively, are omitted. In FIG. 13, the SRAM cell shown in FIG. 15 may be arranged as the SRAM cell C2 instead of the SRAM cell shown in FIG. 14. In this case, in each SRAM cell C2, the buried interconnects 14 and 15 are not connected with the access transistors PG2 and PG1.

According to FIG. 15, the advantages similar to those of FIG. 14 can be obtained.

### Modification 2

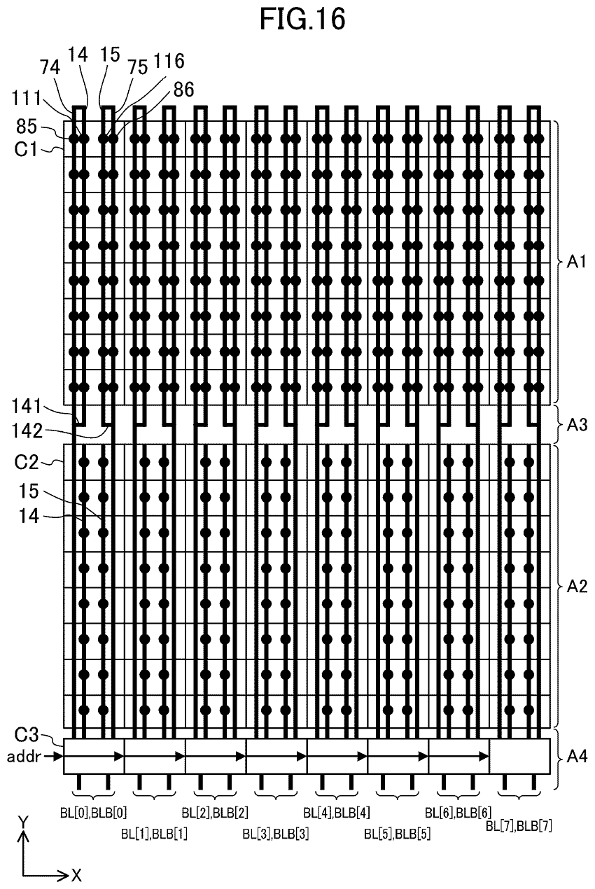

FIG. 16 is a plan view showing another exemplary layout configuration of the circuit block in the semiconductor memory device of the third embodiment. In FIG. 16, as compared with FIG. 12, the SRAM cell C2 is arranged in the sub memory array A2. In FIG. 16, as compared with FIG. 12 and FIG. 13, in the region A3, the buried interconnects 14 and 15 of the sub memory cell array A2 are not connected with the buried interconnects 14 and 15 of the sub memory array A1.

In the region A4, selectors C3 are arranged so as to correspond to each column of the sub memory arrays A1 and A2. The selectors C3 arranged in the region A4 are each connected with the buried interconnects 14 and 15 and lines 74 and 75 of the corresponding SRAM cell C2.

As shown in FIG. 16, the lines 74 and 75 in the sub memory array A1 are connected with the buried interconnects 14 and 15 in each SRAM cell C1 of the same column and in the region A3, and are connected with the selector C3 without being connected with any of the SRAM cells C2 of the same column in the sub memory array A2. The buried interconnects 14 and 15 of the sub memory array A2 are connected with the SRAM cells C2 in the same column, and are connected with the selector C3 without being connected with the buried interconnects 14 and 15 in the sub memory array A1 and the lines 74 and 75 in the sub memory arrays A1 and A2.

The selector C3 receives a selection address signal addr corresponding to the sub memory arrays A1 and A2, and selects a pair of signals of either the buried interconnects 14 and 15 or the lines 74 and 75. The selected pair of signals is connected to the bit line pair BL and BLB, and connected to a reading circuit or a writing circuit (not shown).

In this modification, the bit lines BLB and BL (the buried interconnects 14 and 15 and the lines 74 and 75) in the sub memory array A1 are connected with the selector arranged in the region A4 through the lines 74 and 75 in the sub memory array A2, respectively. The SRAM cells C2 of FIG. 14 in which the lines 74 and 75 are not connected to the access transistors PG2 and PG1 are arranged in the sub memory array A2, and thus the load capacity of the SRAM cells C2 does not occur in the bit lines BLB and BL in the sub memory array A1. Thus, the data in the SRAM cells C1 arranged in the sub memory array A1 can be read out at a high speed.

In this modification, the bit lines BLB and BL (the buried interconnects 14 and 15 and the lines 74 and 75) in the sub memory array A1 may be connected with the selector arranged in the region A4 through the buried interconnects 14 and 15 in the sub memory array A2, respectively. In this case, the lines 74 and 75 in the sub memory array A2 are connected with the SRAM cells C2 in the same column, and are connected with the selector C3 without being connected with the buried interconnects 14 and 15 in the sub memory array A1 and the lines 74 and 75 in the sub memory arrays A1 and A2. In this case, the SRAM cells of FIG. 15 are arranged as the SRAM cells C2 of the sub memory array A2.

Here, by selecting the lines with lower resistance, as operation passage lines that are the bit lines BL and BLB of the SRAM cell C1 in the sub memory array A1, out of the lines 74 and 75 of the SRAM cell C2 in the sub memory array A2 and the buried interconnects 14 and 15 as the pass-through lines that operate, the resistance of the bit lines BL and BLB can be more lowered. Further, by the selector in the region A4 being used to switch the bit lines BL and BLB to be connected, the load capacity of the bit lines BL and BLB charged/discharged during operation can be reduced, and thus the power consumption can be reduced.

In the above embodiments and modifications, each transistor includes three nanosheets, but part or all of the transistors may include a single nanosheet, or two or four or more nanosheets.

In the above embodiments and modifications, the cross-sectional shape of the nanosheet is rectangular, but is not limited to this shape. For example, the shape may be square, circular or elliptical.

In the above embodiments and modifications, the shared-contacts 61 and 62 may be manufactured in the same process as the contacts (gate-contacts) and the local interconnects are manufactured, or may be manufactured in a different process.

In the above embodiments and modifications, the P-type substrate 2 may be a P-well.

According to the present disclosure, in the layout configuration of the SRAM cell where the bit lines are provided in the buried interconnect layer, the semiconductor memory device can operate at a high speed and its writing characteristic can be improved whereas the area of the semiconductor memory device is less increased.
11 to 13 Buried Power Rail
14 to 16 Buried Interconnect
21 to 28 Nanosheets
31 to 36 Gate Line
40 to 49, 50a to 50c Pad
51 to 58 Local Interconnect
61, 62 Shared-Contact
71 to 79 Line
PU1, PU2 Load Transistor
PD1, PD2 Drive Transistor
PG1, PG2 Access Transistor
BL, BLB Bit Line
WBL, WBLB Write-Bit Line
RBL Read-Bit Line
WL Word Line
WWL Write-Word Line
RWL Read-Word Line
A1, A2 Sub Memory Array
A3, A4 Region

What is claimed is:

1. A semiconductor memory device comprising a 1-port SRAM cell, wherein
the 1-port SRAM cell includes
a first transistor having nodes, one of which is connected to a first power source that supplies a first voltage, and another one of which is connected to a first node, and having a gate connected to a second node,
a second transistor having nodes, one of which is connected to the first power source, another one of which is connected to the second node, and having a gate connected to the first node,
a third transistor having nodes, one of which is connected to the first node, another one of which is connected to a second power source that supplies a second voltage different from the first voltage, and having a gate connected to the second node,
a fourth transistor having nodes, one of which is connected to the second node, another one of which is connected to the second power source, and having a gate connected to the first node,
a fifth transistor having nodes, one of which is connected to a first bit line, another one of which is connected to the first node, and having a gate connected to a word line, and
a sixth transistor having nodes, one of which is connected to a second bit line with which the first bit line constitute a complementary bit line pair, and another one of which is connected to the second node, and having a gate connected to the word line,
the first bit line includes
a first buried interconnect formed in a buried interconnect layer and extending in a first direction, and
a first line formed in a first line layer located above the first to sixth transistors and extending in the first direction, and
the second bit line includes
a second buried interconnect formed in the buried interconnect layer and extending in the first direction, and
a second line formed in the first line layer and extending in the first direction.

2. The semiconductor memory device of claim 1, wherein
the 1-port SRAM cell further includes
a first buried power rail formed in the buried interconnect layer, connected to the second power source, and extending in the first direction, and
a third line formed in the buried the first line layer, connected to the second power source, and extending in the first direction.

3. The semiconductor memory device of claim 1, wherein
the 1-port SRAM cell further includes
a second buried power rail formed in the buried interconnect layer, connected to the first power source, and extending in the first direction, and
a fourth line formed in the buried the first line layer, connected to the first power source, and extending in the first direction.

4. The semiconductor memory device of claim 1, wherein
the first line has a line width wider than a line width of the first buried interconnect, and
the second line has a line width wider than a line width of the second buried interconnect.

5. A semiconductor memory device comprising a 2-port SRAM cell, wherein
the 2-port SRAM cell includes
a first transistor having nodes, one of which is connected to a first power source that supplies a first voltage, and another one of which is connected to a first node, and having a gate connected to a second node,
a second transistor having nodes, one of which is connected to the first power source, and another one of which is connected to the second node, and having a gate connected to the first node,
a third transistor having nodes, one of which is connected to the first node, and another one of which is connected to a second power source that supplies a second voltage different from the first voltage, and having a gate connected to the second node,
a fourth transistor having nodes, one of which is connected to the second node, and another one of which is connected to the second power source, and having a gate connected to the first node,
a fifth transistor having nodes, one of which is connected to a first write-bit line, and another one of which is connected to the first node, and having a gate connected to a write-word line,
a sixth transistor having nodes, one of which is connected to a second write-bit line with which the first write-bit line constitute a complementary bit line pair, and another one of which is connected to the second node, and having a gate connected to the write-word line,
a seventh transistor having nodes, one of which is connected to the second power source, and having a gate connected to the second node, and
an eighth transistor having nodes, one of which is connected to another one of the nodes of the seventh transistor, and another one of which is connected to a read-bit line, and having a gate connected to a read-word line,
the first write-bit line includes
a first buried interconnect formed in a buried interconnect layer and extending in a first direction, and
a first line formed in a first line layer located above the first to sixth transistors and extending in the first direction, and
the second write-bit line includes
a second buried interconnect formed in the buried interconnect layer and extending in the first direction, and
a second line formed in the first line layer and extending in the first direction.

6. The semiconductor memory device of claim 5, wherein
the read-bit line includes
a third buried interconnect formed in the buried interconnect layer and extending in the first direction, and
a third line formed in the first line layer and extending in the first direction.

7. The semiconductor memory device of claim 5, wherein
the first line has a line width wider than a line width of the first buried interconnect, and
the second line has a line width wider than a line width of the second buried interconnect.

8. A semiconductor memory device comprising a first sub memory array and a second sub memory array each comprising SRAM cells arranged in an array, wherein
the first sub memory array includes a first bit line and a second bit line that constitute a complementary bit line pair,
the second sub memory array includes a third bit line and a fourth bit line that constitute a complementary bit line pair,
the first bit line includes
a first buried interconnect formed in a buried interconnect layer and extending in a first direction, and
a first line formed in a first line layer located above the buried interconnect layer and extending in the first direction,
the second bit line includes
a second buried interconnect formed in the buried interconnect layer and extending in the first direction, and
a second line formed in the first line layer and extending in the first direction,
the third bit line includes
at least one of a third buried interconnect formed in the buried interconnect layer and extending in the first direction and a third line formed in the first line layer and extending in the first direction, and
the fourth bit line includes
at least one of a fourth buried interconnect formed in the buried interconnect layer and extending in the first direction and a fourth line formed in the first line layer and extending in the first direction.

9. The semiconductor memory device of claim 8, wherein
the third bit line includes
a third buried interconnect formed in the buried interconnect layer and extending in the first direction, and
a third line formed in the first line layer and extending in the first direction,
the fourth bit line includes
a fourth buried interconnect formed in the buried interconnect layer and extending in the first direction, and
a fourth line formed in the first line layer and extending in the first direction,
the first buried interconnect is connected with the third buried interconnect,
the second buried interconnect is connected with the fourth buried interconnect,
the first line is connected with the third line, and
the second line is connected with the fourth line.

10. The semiconductor memory device of claim 9, wherein
a first region is formed between the first sub memory array and the second sub memory array,
the first buried interconnect and the third buried interconnect are connected with the first line and the third line in the first region, and
the second buried interconnect and the fourth buried interconnect are connected with the second line and the fourth line in the first region.

11. The semiconductor memory device of claim 10, wherein
the SRAM cells in the first sub memory array are not connected with the first line and the second line in a region in which the first sub memory array is arranged, and
the SRAM cells in the second sub memory array are not connected with the third line and the fourth line in a region in which the second sub memory array is arranged.

12. The semiconductor memory device of claim 10, wherein
the SRAM cells in the first sub memory array are not connected with the first buried interconnect and the second buried interconnect in a region in which the first sub memory array is arranged, and
the SRAM cells in the second sub memory array are not connected with the third line and the fourth line in a region in which the second sub memory array is arranged.

13. The semiconductor memory device of claim 8, wherein
the third bit line includes a third buried interconnect formed in the buried interconnect layer and extending in the first direction, and
the fourth bit line includes a fourth buried interconnect formed in the buried interconnect layer and extending in the first direction.

14. The semiconductor memory device of claim 8, wherein
the second sub memory array includes
a third line formed in the first line layer and extending in the first direction, and
a fourth line formed in the first line layer and extending in the first direction,
the SRAM cells in the second sub memory array are not connected with the third line and the fourth line in a region in which the second sub memory array is arranged,
a first region is formed between the first sub memory array and the second sub memory array,
the third line is connected with the first line and the first buried interconnect in the first region, and
the fourth line is connected with the second line and the second buried interconnect in the first region.

15. The semiconductor memory device of claim 8, wherein
the second sub memory array includes
a third line formed in the buried interconnect layer and extending in the first direction, and
a fourth line formed in the buried interconnect layer and extending in the first direction,
the SRAM cells in the second sub memory array are not connected with the third line and the fourth line in a region in which the second sub memory array is arranged,
a first region is formed between the first sub memory array and the second sub memory array,
the third line is connected with the first line and the first buried interconnect in the first region, and
the fourth line is connected with the second line and the second buried interconnect in the first region.
